(19) United States
(12) Patent Application Publication
(10) Pub. No.: US 2011/0049668 A1
(43) Pub. Date: Mar. 3, 2011

(54) DEEP TRENCH ISOLATION STRUCTURES BETWEEN HIGH VOLTAGE SEMICONDUCTOR DEVICES AND FABRICATION METHODS THEREOF

(76) Inventors: Ming-Cheng LIN, Taipei City (TW); Wen-Hsun LO, Zhudong Township (TW); Shih-Chieh PU, Yonghe City (TW); Yu-Long CHANG, Hsinchu City (TW)

(21) Appl. No.: 12/552,613

(22) Filed: Sep. 2, 2009

(51) Int. Cl. H01L 29/06; H01L 21/762

(52) U.S. Cl. 257/506; 438/424; 257/E29.02; 257/E21.546

(57) ABSTRACT

Deep trench isolation structures between high voltage semiconductor devices and fabrication methods thereof are presented. The high voltage semiconductor device includes a semiconductor substrate, pluralities of intersecting deep trench isolation structures defining several high voltage semiconductor device regions, and an island at the center of the intersection between the two deep trench isolation structures, wherein the two intersecting deep trench isolation structures h

### BACKGROUND OF THE INVENTION

1. Field of the Invention

The invention relates to deep trench isolation (DTI) structures, and in particular, to deep trench isolation (DTI) structures between high voltage semiconductor devices.

2. Description of the Related Art

In conventional integrated circuit chips, deep trench isolation (DTI) structures are used between high voltage semiconductor devices. DTI technologies are most applicable to high voltage and high power integrated circuit regimes. The use of DTI structures can drastically reduce layout area of devices and effectively prevent electrostatic discharge (ESD) and latch-up effects.

FIG. 1A is a plan view schematically illustrating layout of a conventional high voltage semiconductor device, and FIG. 1B is a schematic cross section of a deep trench isolation (DTI) structure of FIG. 1A taken along line 1B-1B. Referring to FIG. 1A, a high voltage semiconductor chip 10 includes pluralities of high voltage semiconductor devices 12 and longitudinal and transverse intersecting deep trench isolation (DTI) structures 14 therebetween. The width of each DTI structure 14 is depicted as X, while the diagonal width at the intersected center 18 of two intersecting DTI structures 14 is depicted as Y. The diagonal width Y is about 1.4 times of the width X of each DTI structure 14. Referring to FIG. 1B, when dimensions of devices shrink, the profile of α-polysilicon 13 may be budged resulting in edge necking at top corner of the isolation structure and leaving pores or voids 16 in the deep trench isolation structure during deposition. After the α-polysilicon 13 is etched, the surface of the semiconductor substrate 11 is exposed, such that the voids 16 in the deep trench isolation structure connect to external environment. The voids 16 may be encroached by chemicals during subsequent processes affecting performance of the high voltage semiconductor devices. Moreover, after the thermal processes, the voids 16 with encroached chemicals may evaporate causing volume expansion and breaking of the semiconductor substrate 11. The above effects are particularly obvious at intersection areas between two intersecting deep trench isolation structures 14.

### BRIEF SUMMARY OF THE INVENTION

An embodiment of the invention provides deep trench isolation (DTI) structures between high voltage semiconductor devices, comprising: a semiconductor substrate; a plurality of intersecting deep trench isolation structures defining several high voltage semiconductor device regions; and an island at the center of the intersection between the two deep trench isolation structures, wherein the two intersecting deep trench isolation structures have obtuse edges.

Another embodiment of the invention provides deep trench isolation (DTI) structures between high voltage semiconductor devices, comprising: a semiconductor substrate; a plurality of intersecting deep trench isolation structures defining several high voltage semiconductor device regions; and a polygonal island at the center of the intersection between the two deep trench isolation structures, wherein the two intersecting deep trench isolation structures have obtuse edges; and a distance between the obtuse edges and the bevel edges of the polygonal island is a first width, and each of the deep trench isolation structures has a second width, wherein the ratio of the first width to the second width is in a range of about 0.3-0.9.

Another embodiment of the invention provides a method for fabricating deep trench isolation (DTI) structures between high voltage semiconductor devices, comprising: providing a semiconductor substrate; forming a plurality of intersecting deep trenches defining several high voltage semiconductor device regions, wherein a polygonal island is formed at the center of the intersection between the two deep trenches; and filling an isolation material in the deep trenches and etching back the isolation material, thereby forming deep trench isolation structures; wherein the two intersecting deep trench isolation structures have obtuse edges; and a distance between the obtuse edges and the bevel edges of the polygonal island is a first width, and each of the deep trench isolation structures has a second width, wherein the ratio of the first width to the second width is in a range of about 0.3-0.9.

### BRIEF DESCRIPTION OF THE DRAWINGS

The invention can be more fully understood by reading the subsequent detailed description and examples with references made to the accompanying drawings, wherein:

FIG. 1A is a plan view schematically illustrating layout of a conventional high voltage semiconductor device;

FIG. 1B is a schematic cross section of deep trench isolation (DTI) of FIG. 1A taken along line 1B-1B;

FIG. 2A is a schematic plan view of an embodiment of deep trench isolation (DTI) structures between high voltage semiconductor devices of the invention; and

FIG. 2B is a schematic plan view of another embodiment of deep trench isolation (DTI) structures between high voltage semiconductor devices of the invention.

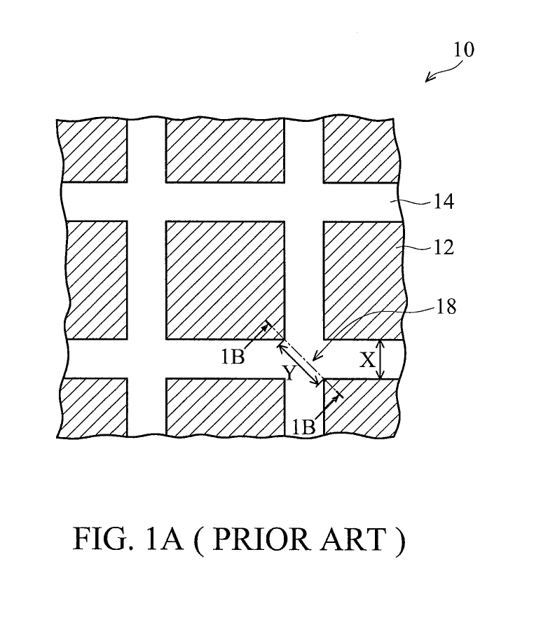

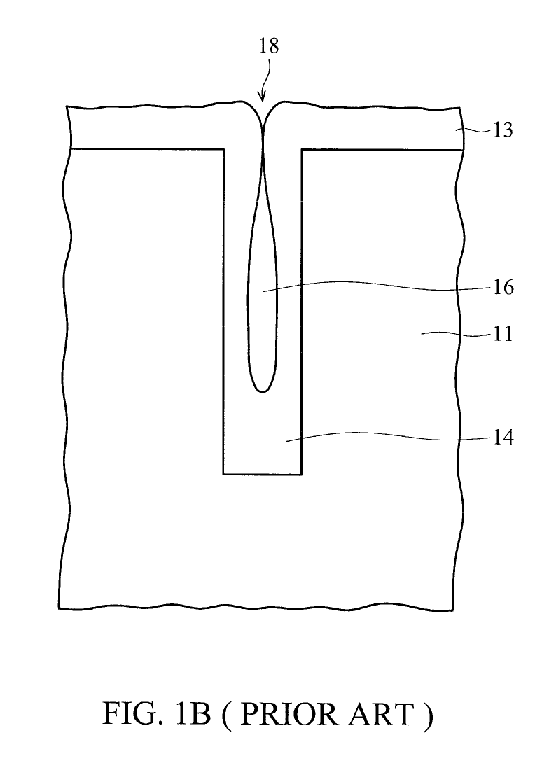

### DETAILED DESCRIPTION OF THE INVENTION

It is to be understood that the following disclosure provides many different embodiments, or examples, for implementing different features of various embodiments. Specific examples of components and arrangements are described below to simplify the present disclosure. These are merely examples and are not intended to be limiting. In addition, the present disclosure may repeat reference numerals and/or letters in the various examples. This repetition is for the purpose of simplicity and clarity and does not in itself indicate a relationship between the various embodiments and/or configurations discussed. Moreover, the formation of a first feature over or on a second feature in the description that follows may include embodiments in which the first and second features are formed indirect contact or not indirect contact.

As key aspects and main features, embodiments of the invention provide an island structure at the center of two intersecting deep trench isolation structures to improve process margins. In one embodiment, the two intersecting deep trench isolation structures have obtuse edges, thereby effectively reducing mechanical and electrical stresses. In another embodiment, the island structure is electrically grounded to improve device performance.

According to an embodiment of the invention, the structure of the deep trench isolation (DTI) structures between high voltage semiconductor devices includes a semiconductor substrate, and a plurality of intersecting deep trench isolation structures defining several high voltage semiconductor device regions. An island is disposed at the center of the intersection between the two deep trench isolation structures, wherein the two intersecting deep trench isolation structures have obtuse edges.

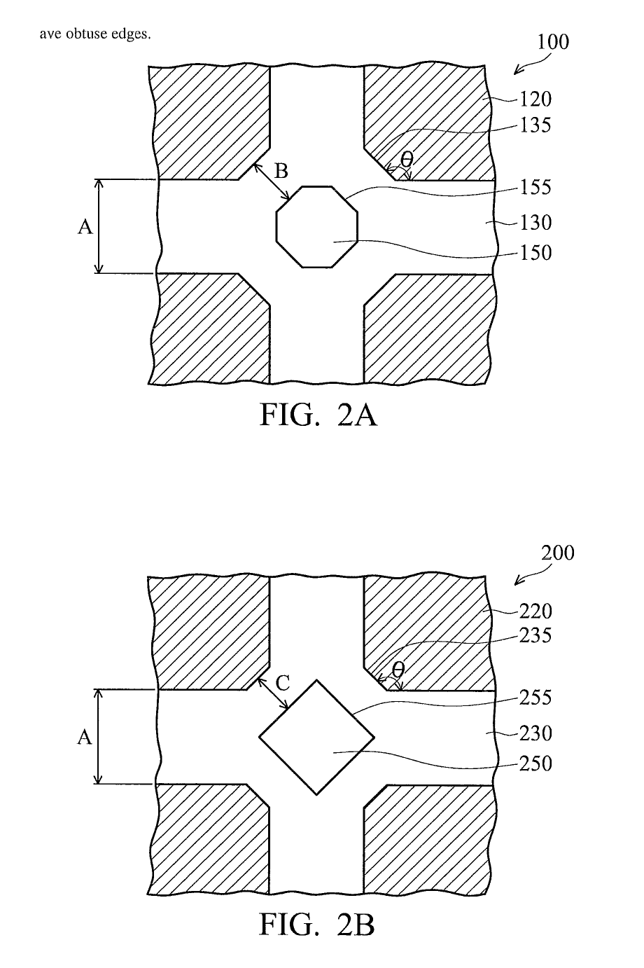

FIG. 2A is a schematic plan view of an embodiment of deep trench isolation (DTI) structures between high voltage semiconductor devices of the invention. Referring to FIG. 2A, a high voltage semiconductor chip 100 includes a semiconductor substrate and pluralities of intersected longitudinal and transverse deep trench isolation structures 130 disposed in the semiconductor substrate, defining several high voltage semiconductor device regions 120. An octagonal island structure 150 is disposed at the center of the intersection between the two deep trench isolation structures 130, wherein the two intersecting deep trench isolation structures have a beveled edge 135 with an obtuse angle θ. For example, an included angle between the obtuse edges 135 and the deep trench isolation may be about 135 degrees. A distance between the beveled edge 135 with an obtuse angle θ and the bevel edges of the octagonal structure is a first width B, and each of the deep trench isolation structures has a second width A, wherein the ratio of the first width B to the second width A is in a range of about 0.3-0.9. In other embodiments, the obtuse edges 135 are parallel with the bevel edges 155 of the octagonal structure 150.

In one embodiment of the invention, the octagonal island structure 150 and the semiconductor substrate are made of the same material. In another embodiment, the octagonal island structure 150 is electrically grounded.

FIG. 2B is a schematic plan view of another embodiment of deep trench isolation (DTI) structures between high voltage semiconductor devices of the invention. Referring to FIG. 2B, a high voltage semiconductor chip 200 includes a semiconductor substrate and pluralities of intersected longitudinal and transverse deep trench isolation structures 230 disposed in the semiconductor substrate, defining several high voltage semiconductor device regions 220. A quadrangle island structure 250 (e.g. a rhombohedral island structure) is disposed at the center of the intersection between the two deep trench isolation structures 230. The two intersecting deep trench isolation structures have a beveled edge 235 with an obtuse angle θ. For example, an included angle between the obtuse edges 235 and the deep trench isolation may be about 135 degrees. A distance between the beveled edge 135 with an obtuse angle θ and the bevel edges of the quadrangle structure is a first width C, and each of the deep trench isolation structures has a second width A, wherein the ratio of the first width C to the second width A is in a range of about 0.3-0.9. In other embodiments, the obtuse edges 235 are parallel with the bevel edges 255 of the quadrangle structure 250.

In one embodiment of the invention, the quadrangle island structure 250 and the semiconductor substrate are made of the same material. In another embodiment, the quadrangle island structure 250 is electrically grounded.

Moreover, embodiments of the invention further provide a method for fabricating deep trench isolation (DTI) structures between high voltage semiconductor devices. First, a semiconductor substrate is provided. Pluralities of intersecting deep trenches are formed defining several high voltage semiconductor device regions, wherein a polygonal island is formed at the center of the intersection between the two deep trenches. An isolation material is filled in the deep trenches, and the isolation material is subsequently etched back, thereby forming deep trench isolation structures. In one embodiment, the deep trench isolation structures comprise polysilicon, silicon oxide, silicon nitride, or other insulation materials. The two intersecting deep trench isolation structures have obtuse edges, and a distance between the obtuse edges and the bevel edges of the polygonal island is a first width, and each of the deep trench isolation structures has a second width, wherein the ratio of the first width to the second width is in a range of about 0.3-0.9.

Accordingly, in the abovementioned embodiments, an island structure is disposed at the center of the intersection between the two deep trench isolation structures such that the interval between the obtuse edges and the bevel edges of the island structure is less than the width of the deep trench isolation. Therefore, pores or voids in the deep trench isolation during deposition are prevented to effectively improve process margins. Since the two intersecting deep trench isolation structures have obtuse edges, mechanical and electrical stresses can be effectively reduced. Furthermore, the island structure is electrically grounded to improve performance of the high voltage semiconductor device.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A deep trench isolation (DTI) structures between high voltage semiconductor devices, comprising:
a semiconductor substrate;
a plurality of intersecting deep trench isolation structures defining several high voltage semiconductor device regions; and
an island at the center of the intersection between the two deep trench isolation structures,
wherein the two intersecting deep trench isolation structures have obtuse edges.

2. The DTI structure as claimed in claim 1, wherein the island comprises a polygonal structure.

3. The DTI structure as claimed in claim 2, wherein the polygonal structure comprises an octagonal structure or a quadrangle structure.

4. The DTI structure as claimed in claim 2, wherein the obtuse edges are parallel with the bevel edges of the polygonal structure.

5. The DTI structure as claimed in claim 4, wherein a distance between the obtuse edges and the bevel edges of the polygonal structure is a first width, and each of the deep trench isolation structures has a second width, and the ratio of the first width to the second width is in a range of about 0.3-0.9.

6. The DTI structure as claimed in claim 1, wherein the island and the semiconductor substrate are made of the same material.

7. The DTI structure as claimed in claim 1, wherein the island is electrically grounded.

8. The DTI structure as claimed in claim 1, wherein the deep trench isolation structures comprise polysilicon, silicon oxide, silicon nitride, or other insulation materials.

9. The DTI structure as claimed in claim 1, wherein an included angle between the obtuse edges and the deep trench isolation is about 135 degrees.

10. A deep trench isolation (DTI) structures between high voltage semiconductor devices, comprising:
a semiconductor substrate;
a plurality of intersecting deep trench isolation structures defining several high voltage semiconductor device regions; and
a polygonal island at the center of the intersection between the two deep trench isolation structures,
wherein the two intersecting deep trench isolation structures have obtuse edges, and
a distance between the obtuse edges and the bevel edges of the polygonal island is a first width, and each of the deep trench isolation structures has a second width, wherein the ratio of the first width to the second width is in a range of about 0.3-0.9.

11. The DTI structure as claimed in claim 10, wherein the polygonal island comprises an octagonal structure or a quadrangle structure.

12. The DTI structure as claimed in claim 10, wherein the obtuse edges are parallel with the bevel edges of the polygonal island.

13. The DTI structure as claimed in claim 10, wherein the polygonal island and the semiconductor substrate are made of the same material.

14. The DTI structure as claimed in claim 10, wherein the polygonal island is electrically grounded.

15. The DTI structure as claimed in claim 10, wherein the deep trench isolation structures comprise polysilicon, silicon oxide, silicon nitride, or other insulation materials.

16. The DTI structure as claimed in claim 10, wherein an included angle between the obtuse edges and the deep trench isolation is about 135 degrees.

17. A method for fabricating deep trench isolation (DTI) structures between high voltage semiconductor devices, comprising:
providing a semiconductor substrate;
forming a plurality of intersecting deep trenches defining several high voltage semiconductor device regions, wherein a polygonal island is formed at the center of the intersection between the two deep trenches; and
filling an isolation material in the deep trenches and etching back the isolation material, thereby forming deep trench isolation structures,
wherein the two intersecting deep trench isolation structures have obtuse edges, and
a distance between the obtuse edges and the bevel edges of the polygonal island is a first width, and each of the deep trench isolation structures has a second width, wherein the ratio of the first width to the second width is in a range of about 0.3-0.9.

18. The method for fabricating a DTI structure as claimed in claim 17, wherein the polygonal island comprises an octagonal structure or a quadrangle structure.

19. The method for fabricating a DTI structure as claimed in claim 17, wherein the obtuse edges are parallel with the bevel edges of the polygonal island.

20. The method for fabricating a DTI structure as claimed in claim 17, wherein the deep trench isolation structures comprise polysilicon, silicon oxide, silicon nitride, or other insulation materials.

21. The method for fabricating a DTI structure as claimed in claim 17, wherein an included angle between the obtuse edges and the deep trench isolation is about 135 degrees.
